(19) United States
(12) Patent Application Publication
(10) Pub. No.: US 2026/0013212 A1
(43) Pub. Date: Jan. 8, 2026

(54) METALIZATION STACK RESISTOR

(71) Applicant: Altera Corporation, San Jose, CA (US)

(72) Inventors: Avi MORLEVY, Nahariya (IL); Zeev TOROKER, Haifa (IL)

(21) Appl. No.: 19/326,444

(22) Filed: Sep. 11, 2025

(51) Int. Cl. H10D 84/80; H01L 23/522; H10D 1/47

(52) U.S. Cl. CPC H10D 84/817; H01L 23/5228; H10D 1/47

(57) ABSTRACT

Some examples include a resistor structure formed from interconnect line segments in multiple metalization layers of an integrated circuit device. The line segments include contacts from at least one dummy transistor.

### TECHNICAL FIELD

Embodiments relate to the field of semiconductor devices and to resistor structures in integrated circuit devices.

### BRIEF DESCRIPTION OF THE DRAWINGS

The disclosure may best be understood by referring to the following description and accompanying drawings that are used to illustrate embodiments. In the drawings:

FIG. 1 is a schematic diagram showing a not-to-scale side view of a metallization stack section for an integrated circuit with a metal layer resistor in accordance with some embodiments.

FIGS. 2A-2C are diagrams showing interconnect line layouts for a multi-level resistor in accordance with some embodiments.

FIG. 3A is a diagram showing a sense circuit for implementing a multi-input signal sense circuit using bootstrap switches (BSw) in accordance with some embodiments.

FIG. 3B is a diagram showing a bootstrap switch with a metal layer resistor in accordance with some embodiments.

FIG. 4 illustrates an example computing system including sense circuitry as disclosed herein in accordance with some embodiments.

FIG. 5 illustrates a block diagram of an example processor that may have one or more cores and an integrated memory controller in accordance with some embodiments.

FIG. 6 is a block diagram illustrating a parallel processing computing system configured to implement one or more aspects of the examples described herein in accordance with some embodiments.

### DETAILED DESCRIPTION

With semiconductor devices, it is generally desirable to be able to implement circuits such as signal sensing circuits that occupy as little area as possible. For example, processors or programmable gate array integrated circuits (ICs) often include sense circuits for monitoring high-frequency clocks with multiple phases. Often, a relatively large number of sense circuits are used, and thus, it can be important for them to occupy a relatively small footprint.

Many of these circuits require the use of mid to high value resistors (e.g., 1 KΩ to 100 KΩ). Unfortunately, implementing such resistors has traditionally consumed a significant amount of space. For example, thin-film resistors (TFRs) are commonly used for implementing medium and large resistors. Thin film resistors are particularly useful in applications that require precision and temperature stability. However, a significant area is usually required to achieve these resistance values. For instance, a TFR resistor of 5 kΩ can occupy an area in the neighborhood of 15 square microns. This poses a challenge for sensing circuits whose allotted area budgets may be limited to much smaller footprints.

Another essential consideration is capacitance. Some sense circuits can require low parasitic capacitances between the resistor and supply reference (e.g., ground) nodes. For instance, with some conventional medium to high range (e.g., 5 kΩ) thin film resistor implementations, the capacitances can reach 5 fF, which can be problematic, especially for high-speed signal monitoring applications.

Accordingly, new resistor solutions would be desired.

In some embodiments, multiple metalization layer interconnect line segments, including trench contacts, along with metal segments from other lower metal stack layers, are used to achieve a medium or high resistance resistor that occupies a relatively small area. In some embodiments, such resistors may use serpentine-shaped layouts formed through trench contact and lower metal layer segments. Such designs allow for medium and high resistances with low parasitic capacitances, e.g., advanced processes that don't use channel connections with a substrate. Moreover, they can fit into small areas, such as within analog layout regions. For example, with these approaches, a metal resistor that can be up to 70 times smaller than a comparable thin film resistor for achieving medium or higher resistance values and with reduced parasitic capacitances may be attained.

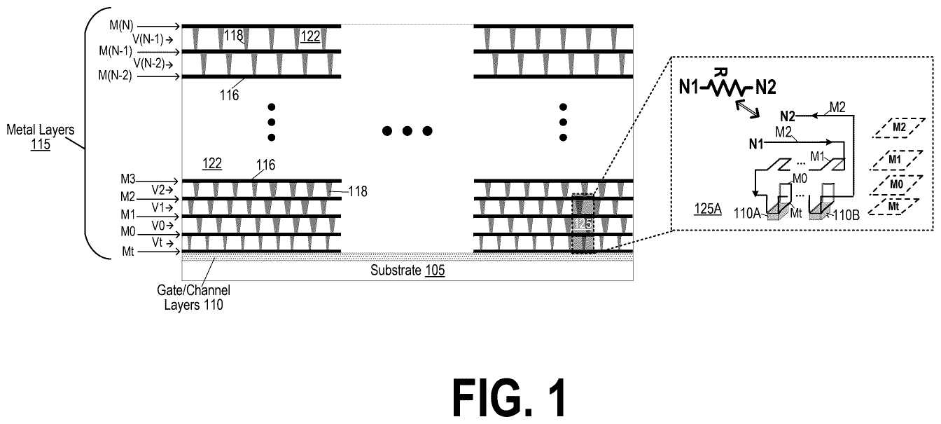

FIG. 1 is a schematic diagram showing a not-to-scale side view of a metallization stack section for an integrated circuit with a metal layer resistor in accordance with some embodiments. For example, this integrated circuit may use gate-all-around (GAA) transistors formed on a substrate 105 (or other support structure, such as with backside power delivery implementations). The integrated circuit (IC) includes a transistor (channel/gate structure) layer 110 disposed between the substrate 105 and a metallization stack 115. The metallization stack 115 includes a series of metal layers (Mt through M(N)) electrically coupled together through vias in via layers (Vt through V(N−1)), which are interleaved between the metal layers. The number of layers (N+2 in this example) can vary, depending on IC complexity or other design considerations. For example, some advanced devices can have 13 or more layers.

The metallization layers include metal (and/or other conductive material) interconnect lines 116 (also referred to simply as lines, segments, or line segments), selectively coupled to one another through the stack by way of vias 118. They serve to connect circuits formed from transistor layer transistors to each other and to circuits outside of the IC. The metal layers (Mt through M(N)) are separated by intermetal layers (IML) formed from a dielectric material 122. The dielectric material electrically insulates the various interconnect lines from each other and also ideally provides at least some structural stability for the metallization stack assembly. The metal stack 115 also typically includes floating metal “fill” lines that are added to compensate for otherwise insufficiently occupied areas to satisfy DRC (design rule checking) metallization density requirements.

Depending on specific design rules, the interconnect lines within each layer are typically disposed within spaced apart “track” locations. For most of the layers, the tracks may be positioned along an X or Y axis, aligned in parallel or perpendicularly with one another. That is, within these layers, lines may be horizontally and/or vertically aligned and thus, separate line segments in a layer may be coupled to one another at perpendicular intersections. On the other hand, with some implementations, lower metal layers (e.g., Mt trench contact and M0 layers) may have lines that are aligned along the same axis, e.g., all horizontal or vertical, and thus, need to connect with other lines, in other layers, through vias.

With such a three-dimensional “grid” network of metal track positions, an enormous variety and quantity of signal line configurations can be attained with strategically placed vias connecting specific line segments at particular locations. As indicated in the figure (not to scale), the metal lines and vias are typically larger at the higher layers with larger spaces between them. The upper layers routing and interconnecting various components, as well as distributing power and clock signals across the chip. However, chip makers have been turning to different approaches whereby the power lines are removed from the top-side stack and instead provided to the transistors through the chip's backside. This technology is called backside power delivery. The lower and mid-level layers (also called the front metal layers) are generally used for interconnecting the numerous circuits and circuit components that make up the integrated circuit.

With particular relevance to this disclosure, the integrated circuit includes resistors such as a resistor 125 formed from metal layer lines, including contacts from the trench layer (Mt). A more detailed schematic view of such a resistor is shown at 125A. (Note that this depiction is not to scale but rather is used to illustrate a relative location for the resistor within the context of an IC device metallization stack.) With this example, a resistor R is coupled between the first and second nodes (N1, N2) through interconnect lines in the trench contact, M0, M1, and M2 layers.

The input and output ports (or nodes N1, N2) are implemented with M2 line segments, while the remaining portions are implemented with M1, M0, and Mt lines. The lines are series-connected between the N1 and N2 nodes, as illustrated. With this example, serpentine layouts are used in the M1 layers for its horizontally and vertically aligned segments, while a serpentine layout is also used with combinations of perpendicularly aligned segments from the M0 and Mt layers, alternately connected through the Mt vias (Vt).

It is noted that most of the resistance for this resistor comes from the M0 and Mt lines, which may be configured to achieve a desired resistance. Also note that dummy transistors (e.g., 110A, 110B) are included to facilitate use of their trench contacts as Mt layer line segments for the resistor. For example, the resistor could be formed using full dummy NMOS (N-type metal oxide semiconductor) and PMOS (P-type MOS) devices, each, for example, with any allowed number of TCN (trench contact) fingers. In some embodiments, this can allow for the resistor to use the TCN metal layer, which typically has specific DRC rules that necessitate the placement of full dummy transistors to comply with DRC density and other rules.

As used herein, the term “serpentine” refers to any interconnect path, formed from lines or line segments, that changes direction multiple times between opposite ends of the path. In the depicted embodiment, for example, the serpentine segments form “U” shaped sections, akin to a square wave, but any other shapes that allow for a longer path within a defined area may be used. For example, the path sections could form “V” or “W” shapes, and if allowed by the process design rules, they could be curved, as with sinusoidal-shaped paths. Accordingly, the term serpentine encompasses square, sawtooth, pulse train, ramp, and other curve configurations that are allowed by a design process and that alternates direction to accommodate a longer distance within a given area.

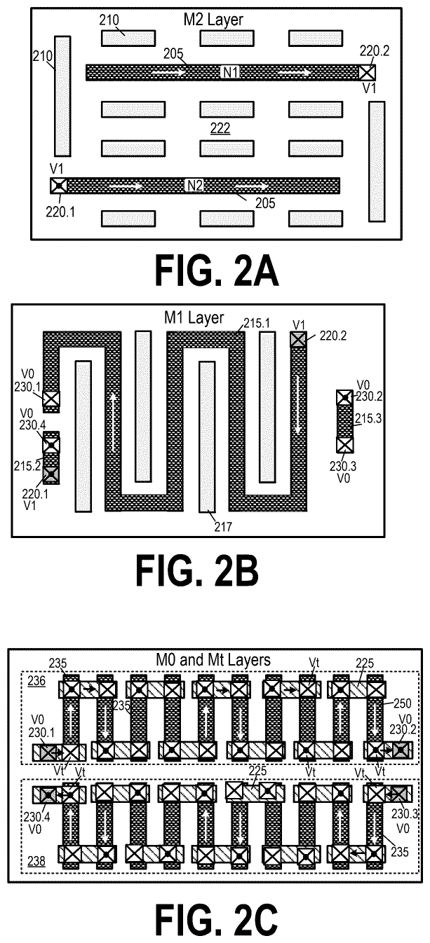

FIGS. 2A-2C are diagrams showing interconnect line layouts for a multi-level resistor in accordance with some embodiments. The depicted regions are generally the same in area (e.g., about 600×360 nm) and are aligned with each other, occupying a common footprint of the semiconductor device.

FIG. 2A shows the M2 portions of the resistor. The M2 layer has resistor line segments 205, as well as other line segments 210, which may be used for other signals or to comply with density constraints. For this example, there are two resistor line segments (N1, N2) in the M2 layer. For ease of understanding and description of the resistor's path through the metal layers, it will be assumed that a DC current flows into the N1 line node and out of the N2 line node. Arrows are used in the figures to indicate the current pathway through the resistor. Here, current flows into N1 and down to the resistor line segments in the M1 layer through a via V1 (220.1).

FIG. 2B shows the M1 portions of the resistor. The M1 layer includes resistor line segments 215 and other line segments 217. The resistor segments 215 include a serpentine-shaped line path 215.1 that is formed from M1 segments that are directed in both X and Y directions. The example current path comes down from the M2 layer through via V1 (220.2) and from here proceeds through the serpentine-shaped resistor line portion 215.1 until it reaches via V0 (230.1). From here, it proceeds downward into the M0 layer.

The M1 resistor line segments 215 also include a first isolated segment 215.2 for coupling M0 and Mt segments to the M2 layer and a second isolated segment 215.3 for coupling different sections of the M0 and Mt segments to one another. (Note that for easier understanding, vias are designated with a box containing an “X” and shaded differently for different via layers. In addition, for the current pathway example, vias with current coming out of the page include an added dot in the middle of a boxed X, whereas only a simple X is used when the path goes into the page to the next, downward layer.)

FIG. 2C shows the M0 and Mt portions of the resistor. With this example, the M0 layer includes only horizontally (X axis) aligned segments 225, while the Mt layer includes only vertically aligned (Y axis) segments 235 that are beneath the M0 segments. With some advanced process implementations, lower metal layers can often have design rules that require line segments to be aligned in a single direction.

The Mt sections 235 are grouped into first and second sections 236, 238. They each correspond to TCN fingers for an associated dummy transistor. So, with this resistor example, there are two dummy types of transistors (e.g. section 236 consists of PMOS dummy transistors while section 238 consists of NMOS dummy transistors), each providing 10 Mt “fingers” (contact segments). For each section, M0 and Mt segments are alternately coupled to one another in a serpentine configuration through the Vt vias, as is indicated.

Returning to the description of the current path through the resistor, the path comes down from the M1 layer by way of via V0 (230.1). It proceeds through the serpentine-shaped first section 236, alternating between M0 and Mt segments as indicated. When it comes to the end of the section, it actually returns upward to the M1 layer by way of via V0 (230.2). It does this to be coupled to the second section 238 through the isolated M1 resistor segment 215.3, which is coupled to the second section 238 through via V0 (230.3). (In some implementations, M0 or other layer segments may be used to couple trench contacts to one another, even when they are aligned in the same direction.)

From here, the pathway proceeds through the second serpentine section until it reaches via V0 (230.4). Then, through isolated resistor line segment 215.2 and via V1 (220.1), it returns to the M2 layer at the second node N2.

Note that with this example, metal trench contacts are used for resistor lines, but in some approaches, poly contacts could additionally or alternatively be used. According to some process design rules, a DC current should not flow through the poly layer. However, if allowed, poly segments could be utilized to achieve higher resistances. It should also be noted that with advanced process implementations, e.g., advanced gate-all-around (GAA) transistors, it is possible to implement the transistors without having a terminal connected to the substrate, namely, these are three-terminal transistors without a bulk connection to supply. That is, with older transistor technologies and designs, it was often necessary to tie some of the N-type transistor sources' bulk terminals to a ground reference and P-type transistors' bulk terminal to a supply reference. This, however, would likely introduce relatively large amounts of parasitic capacitance to metal resistor structures as disclosed herein. Accordingly, it may be advantageous to avoid substrate connections to dummy transistors when they are being used for their trench contacts in resistor implementations, especially if lower parasitic capacitance is desired.

Electrical parameters achieved for example resistor, such as the resistor of FIGS. 2A-2C are summarized in the table below.

| Parameter | Nominal | | Hot (T = 125 C.) | | Cold (T = −40 C.) | |
|---|---|---|---|---|---|---|
| Resistance | 4.5 | kΩ | 5.4 | kΩ | 3.4 | kΩ |
| Capacitance | 0.075 | fF | 0.08 | fF | 0.079 | fF |

The following table compares aspects of a 5 K ohm metal layer resistor design with a comparable TFR counterpart.

| Parameter | TFR | | New metal resistor | |
|---|---|---|---|---|
| Resistance | 5.32k | kQ | 5.4 | kOhm |
| Capacitance | 5.4 | fF | 0.075 | fF |
| Area | 15.113 × 1 | um\hat{ }2 | 0.6 × 0.36 | um\hat{ }2 |

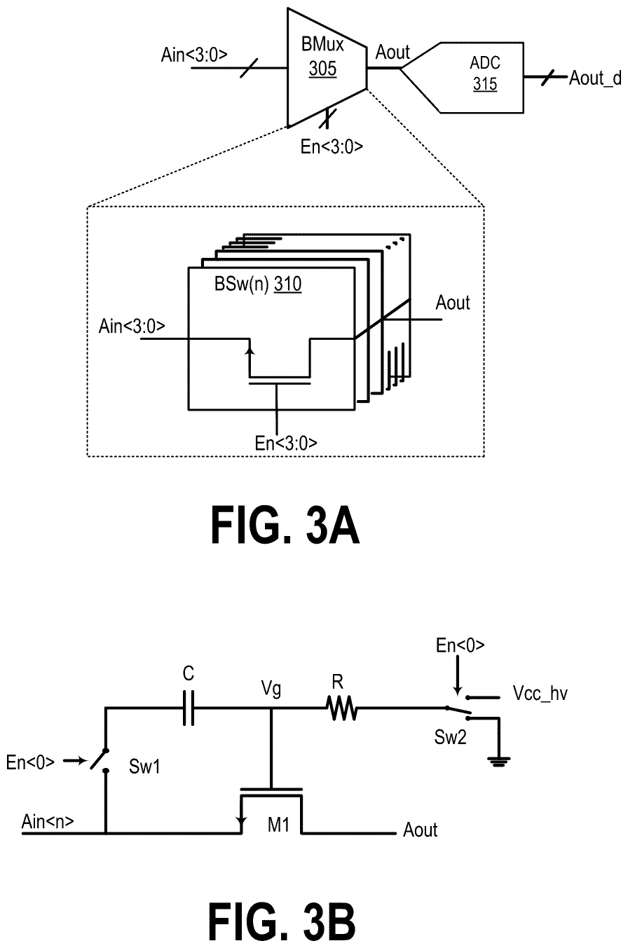

FIG. 3A is a diagram showing a sense circuit for implementing a multi-input signal sense circuit using bootstrap switches (BSw) in accordance with some embodiments. The circuit includes a 4:1 bootstrap switch multiplexer (BMux) 305 coupled with an analog-to-digital converter (ADC) 315. The BMux receives at its four inputs four different signals (Ain<3:0>). For example, the analog signals may be clock signals that are to be monitored or otherwise measured.

A digital selection signal (En<3:0>) selects one of the four inputs, which is then provided at the BMux output (Aout) as seen in BSw(n) 310. From here, the selected signal (Aout) is converted to a digital equivalent and provided as Aout_d at ADC 315.

FIG. 3B is a diagram showing a bootstrap switch with a metal layer resistor in accordance with some embodiments. The bootstrap switch circuit requires a resistor with a relatively high resistance value (e.g., 5 K Ohm) while occupying a compact area and having low parasitic capacitance. With some implementations, this bootstrap switch may be part of a multiplexer such as the BMux of FIG. 3A and should be positioned close to high-speed clocks as part of a clock-sensing block.

The bootstrap switch includes N-type transistor M1, metal layer resistor R, capacitor C, and switches Sw1, Sw2, coupled together as shown. When switches Sw1, Sw2 are closed, the bootstrap switch is activated to provide the selected Ain at the output (Aout). When this occurs, the supply (Vcc_hv), e.g., 1.2 V, is applied at the resistor side connected to Sw2, which turns on M1 and maintains a nearly constant bias across the gate-source of the transistor equals to difference between Vcc_hv and the average Ain<n> voltage to maintain its drain-source resistance relatively constant as the signal (Ain) is being monitored. Depending on specific design considerations, e.g., range of input signal frequencies, a suitably sized resistor R may be desired to achieve an appropriate RC time constant much larger than the time period of the Ain<n> signal for achieving a suitably consistent operational gate-source bias across the transistor.

In some integrated circuit applications, such as with field programmable gate array (FPGA) devices, numerous instances of such bootstrap switches may be utilized. Accordingly, aggressive area constraints may be placed on each of the BSw circuits. For example, in some implementations, area budgets for a bootstrap switch may be in the neighborhood of 0.55 μm×1.8 μm. Thus, it can be seen that the use of metal layer resistors such as those described herein can be helpful in achieving such demanding design parameters.

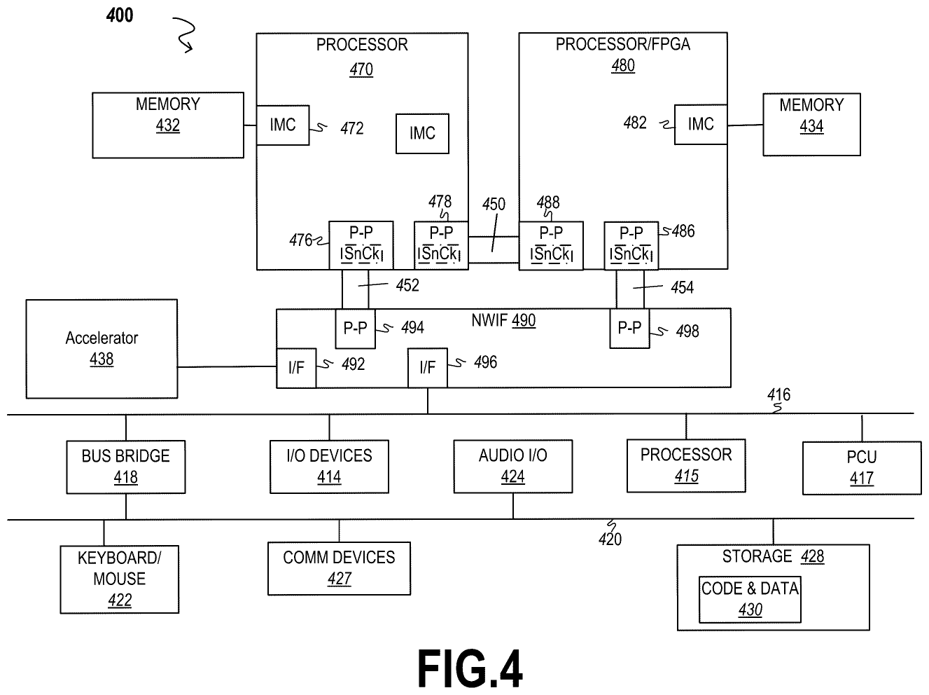

FIG. 4 illustrates an example computing system in accordance with some embodiments. Multiprocessor system 400 is an interfaced system and includes a plurality of processors, including a first processor 470 and a second processor 480, coupled via an interface 450 such as a point-to-point (P-P) interconnect, a fabric, and/or bus. In some examples, the first processor 470 and the second processor 480 are homogeneous. In some examples, first processor 470 and the second processor 480 are heterogenous. Though the example system 400 is shown to have two processors, the system may have three or more processors, or may be a single processor system. In some examples, the computing system is implemented, wholly or partially, with a system on a chip (SoC) or a multi-chip (or multi-chiplet) module, in the same or in different package combinations.

Processors 470 and 480 are shown including integrated memory controller (IMC) circuitry 472 and 482, respectively. Processor 470 also includes interface circuits 476 and 478, along with core sets. Similarly, second processor 480 includes interface circuits 486 and 488, along with a core set as well. A core set generally refers to one or more compute cores that may or may not be grouped into different clusters, hierarchal groups, or groups of common core types. Cores may be configured differently for performing different functions and/or instructions at different performance and/or power levels. The processors may also include other blocks such as memory and other processing unit engines.

Processors 470, 480 may exchange information via the interface 450 using interface circuits 478, 488. IMCs 472 and 482 couple the processors 470, 480 to respective memories, namely a memory 432 and a memory 434, which may be portions of main memory locally attached to the respective processors.

Processors 470, 480 may each exchange information with a network interface (NW I/F) 490 via individual interfaces 452, 454 using interface circuits 476, 494, 486, 498. The network interface 490 (e.g., one or more of an interconnect, bus, and/or fabric, and in some examples is a chipset) may optionally exchange information with a coprocessor 438 via an interface circuit 492. In some examples, the coprocessor 438 is a special-purpose processor, such as, for example, a high-throughput processor, a network or communication processor, compression engine, graphics processor, general purpose graphics processing unit (GPGPU), neural-network processing unit (NPU), embedded processor, or the like.

A shared cache (not shown) may be included in either processor 470, 480 or outside of both processors, yet connected with the processors via an interface such as P-P interconnect, such that either or both processors' local cache information may be stored in the shared cache if a processor is placed into a low power mode.

Network interface 490 may be coupled to a first interface 416 via interface circuit 496. In some examples, first interface 416 may be an interface such as a Peripheral Component Interconnect (PCI) interconnect, a PCI Express interconnect, or another I/O interconnect. In some examples, first interface 416 is coupled to a power control unit (PCU) 417, which may include circuitry, software, and/or firmware to perform power management operations with regard to the processors 470, 480 and/or co-processor 438. PCU 417 provides control information to one or more voltage regulators (not shown) to cause the voltage regulator(s) to generate the appropriate regulated voltage(s). PCU 417 also provides control information to control the operating voltage generated. In various examples, PCU 417 may include a variety of power management logic units (circuitry) to perform hardware-based power management. Such power management may be wholly processor controlled (e.g., by various processor hardware, and which may be triggered by workload and/or power, thermal or other processor constraints) and/or the power management may be performed responsive to external sources (such as a platform or power management source or system software).

PCU 417 is illustrated as being present as logic separate from the processor 470 and/or processor 480. In other cases, PCU 417 may execute on a given one or more of cores (not shown) of processor 470 or 480. In some cases, PCU 417 may be implemented as a microcontroller (dedicated or general-purpose) or other control logic configured to execute its own dedicated power management code, sometimes referred to as P-code. In yet other examples, power management operations to be performed by PCU 417 may be implemented externally to a processor, such as by way of a separate power management integrated circuit (PMIC) or another component external to the processor. In yet other examples, power management operations to be performed by PCU 417 may be implemented within BIOS or other system software. Along these lines, power management may be performed in concert with other power control units implemented autonomously or semi-autonomously, e.g., as controllers or executing software in cores, clusters, IP blocks and/or in other parts of the overall system.

Various I/O devices 414 may be coupled to first interface 416, along with a bus bridge 418 which couples first interface 416 to a second interface 420. In some examples, one or more additional processor(s) 415, such as coprocessors, high throughput many integrated core (MIC) processors, GPGPUs, accelerators (such as graphics accelerators or digital signal processing (DSP) units), field programmable gate arrays (FPGAs), or any other processor, are coupled to first interface 416. In some examples, second interface 420 may be a low pin count (LPC) interface. Various devices may be coupled to second interface 420 including, for example, a keyboard and/or mouse 422, communication devices 427 and storage circuitry 428. Storage circuitry 428 may be one or more non-transitory machine-readable storage media as described below, such as a disk drive or other mass storage device which may include instructions/code and data 430 and may implement the storage in some examples. Further, an audio I/O 424 may be coupled to second interface 420. Note that other architectures than the point-to-point architecture described above are possible. For example, instead of the point-to-point architecture, a system such as multiprocessor system 400 may implement a multi-drop interface or other such architecture.

Processor cores may be implemented in different ways, for different purposes, and in different processors. For instance, implementations of such cores may include: 1) a general purpose in-order core intended for general-purpose computing; 2) a high-performance general purpose out-of-order core intended for general-purpose computing; 3) a special purpose core intended primarily for graphics and/or scientific (throughput) computing. Implementations of different processors may include: 1) a CPU including one or more general purpose in-order cores intended for general-purpose computing and/or one or more general purpose out-of-order cores intended for general-purpose computing; and 2) a coprocessor including one or more special purpose cores intended primarily for graphics and/or scientific (throughput) computing. Such different processors lead to different computer system architectures, which may include: 1) the coprocessor on a separate chip from the CPU; 2) the coprocessor on a separate die in the same package as a CPU; 3) the coprocessor on the same die as a CPU (in which case, such a coprocessor is sometimes referred to as special purpose logic, such as integrated graphics and/or scientific (throughput) logic, or as special purpose cores); and 4) a system on a chip (SoC) that may be included on the same die as the described CPU (sometimes referred to as the application core(s) or application processor(s)), the above described coprocessor, and additional functionality. Example core architectures are described next, followed by descriptions of example processors and computer architectures.

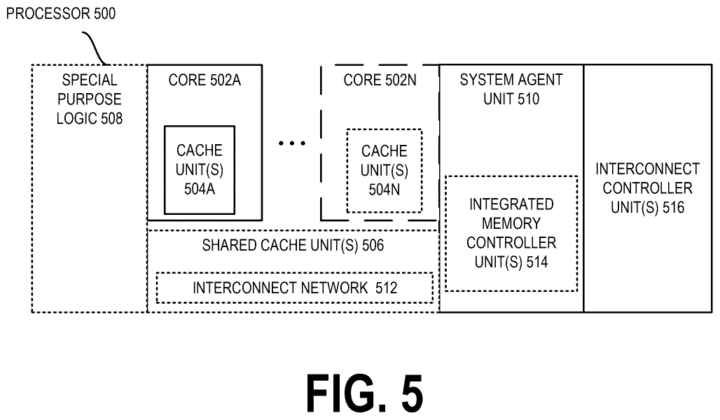

FIG. 5 illustrates a block diagram of an example processor that may have one or more cores and an integrated memory controller in accordance with some embodiments. The solid lined boxes illustrate a processor and/or SoC 500 with a single core 502(A), system agent unit circuitry 510, and a set of one or more interface controller unit(s) circuitry 516, while the optional addition of the dashed lined boxes illustrates an alternative processor and/or SoC 500 with multiple cores 502(A)-(N), a set of one or more integrated memory controller unit(s) circuitry 514 in the system agent unit circuitry 510, and special purpose logic 508, as well as a set of one or more interface controller unit(s) circuitry 516. Note that the processor and/or SoC 500 may be one of the processors 470 or 480, or co-processor 438 or 415 of FIG. 4.

Thus, different implementations of the processor and/or SoC 500 may include: 1) a CPU with the special purpose logic 508 being a high-throughput processor, a network or communication processor, a compression engine, a graphics processor, a general purpose graphics processing unit (GPGPU), a neural-network processing unit (NPU), an embedded processor, a security processor, a matrix accelerator, an in-memory analytics accelerator, a compression accelerator, a data streaming accelerator, data graph operations, or the like (which may include one or more cores, not shown), and the cores 502(A)-(N) being one or more general purpose cores (e.g., general purpose in-order cores, general purpose out-of-order cores, or a combination of the two); 2) a co-processor with the cores 502(A)-(N) being a large number of special purpose cores intended primarily for graphics and/or scientific (throughput); and 3) a co-processor with the cores 502(A)-(N) being a large number of general purpose in-order cores. Thus, the processor and/or SoC 500 may be a general-purpose processor, co-processor or special-purpose processor, such as, for example, a network or communication processor, compression engine, graphics processor, GPGPU (general purpose graphics processing unit), a high throughput many integrated core (MIC) co-processor (including 30 or more cores), embedded processor, or the like. The processor may be implemented on one or more chips. The processor and/or SoC 500 may be a part of and/or may be implemented on one or more substrates using any of a number of process technologies, such as, for example, complementary metal oxide semiconductor (CMOS), bipolar CMOS (BiCMOS), P-type metal oxide semiconductor (PMOS), or N-type metal oxide semiconductor (NMOS).

A memory hierarchy includes one or more levels of cache unit(s) circuitry 504(A)-(N) within the cores 502(A)-(N), a set of one or more shared cache unit(s) circuitry 506, and external memory (not shown) coupled to the set of integrated memory controller unit(s) circuitry 514. The set of one or more shared cache unit(s) circuitry 506 may include one or more mid-level caches, such as level 2 (L2), level 3 (L3), level 4 (L4), or other levels of cache, such as a last level cache (LLC), and/or combinations thereof. While in some examples interface network circuitry 512 (e.g., a ring interconnect) interfaces the special purpose logic 508 (e.g., integrated graphics logic), the set of shared cache unit(s) circuitry 506, and the system agent unit circuitry 510, alternative examples use any number of well-known techniques for interfacing such units. In some examples, coherency is maintained between one or more of the shared cache unit(s) circuitry 506 and cores 502(A)-(N). In some examples, interface controller unit(s) circuitry 516 couple the cores 502(A)-(N) to one or more other devices 518 such as one or more I/O devices, storage, one or more communication devices (e.g., wireless networking, wired networking, etc.), etc.

In some examples, one or more of the cores 502(A)-(N) are capable of multi-threading. The system agent unit circuitry 510 includes those components coordinating and operating cores 502(A)-(N). The system agent unit circuitry 510 may include, for example, power control unit (PCU) circuitry and/or display unit circuitry (not shown). The PCU may be or may include logic and components needed for regulating the power state of the cores 502(A)-(N) and/or the special purpose logic 508 (e.g., integrated graphics logic). The display unit circuitry is for driving one or more externally connected displays.

The cores 502(A)-(N) may be homogenous in terms of instruction set architecture (ISA). Alternatively, the cores 502(A)-(N) may be heterogeneous in terms of ISA; that is, a subset of the cores 502(A)-(N) may be capable of executing an ISA, while other cores may be capable of executing only a subset of that ISA or another ISA.

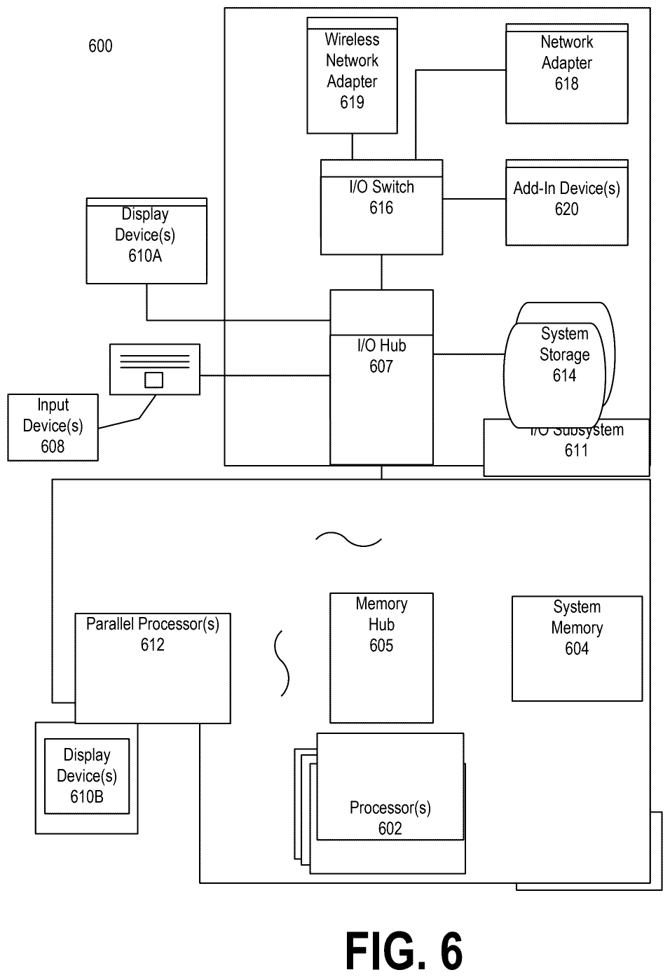

FIG. 6 is a block diagram illustrating a parallel processing computing system 600 configured to implement one or more aspects of the examples described herein. The computing system 600 includes a processing subsystem 601 having one or more processor(s) 602 and a system memory 604 communicating via an interconnection path that may include a memory hub 605. The memory hub 605 may be a separate component within a chipset component or may be integrated within the one or more processor(s) 602. The memory hub 605 couples with an I/O subsystem 611 via a communication link 606. The I/O subsystem 611 includes an I/O hub 607 that can enable the computing system 600 to receive input from one or more input device(s) 608. Additionally, the I/O hub 607 can enable a display controller, which may be included in the one or more processor(s) 602, to provide outputs to one or more display device(s) 610A. In some examples the one or more display device(s) 610A coupled with the I/O hub 607 can include a local, internal, or embedded display device.

The processing subsystem 601, for example, includes one or more parallel processor(s) 612 coupled to memory hub 605 via a bus or communication link 613. The communication link 613 may be one of any number of standards-based communication link technologies or protocols, such as, but not limited to PCI Express, or may be a vendor specific communications interface or communications fabric. The one or more parallel processor(s) 612 may form a computationally focused parallel or vector processing system that can include a large number of processing cores and/or processing clusters, such as a many integrated core (MIC) processor. For example, the one or more parallel processor(s) 612 form a graphics processing subsystem that can output pixels to one of the one or more display device(s) 610A coupled via the I/O hub 607. The one or more parallel processor(s) 612 can also include a display controller and display interface (not shown) to enable a direct connection to one or more display device(s) 610B.

Within the I/O subsystem 611, a system storage unit 614 can connect to the I/O hub 607 to provide a storage mechanism for the computing system 600. An I/O switch 616 can be used to provide an interface mechanism to enable connections between the I/O hub 607 and other components, such as a network adapter 618 and/or wireless network adapter 619 that may be integrated into the platform, and various other devices that can be added via one or more add-in device(s) 620. The add-in device(s) 620 may also include, for example, one or more external graphics processor devices, graphics cards, and/or compute accelerators. The network adapter 618 can be an Ethernet adapter or another wired network adapter. The wireless network adapter 619 can include one or more of a Wi-Fi, Bluetooth, near field communication (NFC), or other network device that includes one or more wireless radios.

The computing system 600 can include other components not explicitly shown, including USB or other port connections, optical storage drives, video capture devices, and the like, which may also be connected to the I/O hub 607. Communication paths interconnecting the various components in FIG. 6 may be implemented using any suitable protocols, such as PCI (Peripheral Component Interconnect) based protocols (e.g., PCI-Express), or any other bus or point-to-point communication interfaces and/or protocol(s), such as the NVLink high-speed interconnect, Compute Express Link™ (CXL™) (e.g., CXL.mem), Infinity Fabric (IF), Ethernet (IEEE 802.3), remote direct memory access (RDMA), InfiniBand, Internet Wide Area RDMA Protocol (iWARP), Transmission Control Protocol (TCP), User Datagram Protocol (UDP), quick UDP Internet Connections (QUIC), RDMA over Converged Ethernet (RoCE), Intel QuickPath Interconnect (QPI), Intel Ultra Path Interconnect (UPI), Intel On-Chip System Fabric (IOSF), Omnipath, HyperTransport, Advanced Microcontroller Bus Architecture (AMBA) interconnect, OpenCAPI, Gen-Z, Cache Coherent Interconnect for Accelerators (CCIX), 3GPP Long Term Evolution (LTE) (4G), 3GPP 5G, and variations thereof, or wired or wireless interconnect protocols known in the art. In some examples, data can be copied or stored to virtualized storage nodes using a protocol such as non-volatile memory express (NVMe) over Fabrics (NVMe-oF) or NVMe.

The one or more parallel processor(s) 612 may incorporate circuitry optimized for graphics and video processing, including, for example, video output circuitry, and constitutes a graphics processing unit (GPU). Alternatively or additionally, the one or more parallel processor(s) 612 can incorporate circuitry optimized for general purpose processing, while preserving the underlying computational architecture, described in greater detail herein. Components of the computing system 600 may be integrated with one or more other system elements on a single integrated circuit. For example, the one or more parallel processor(s) 612, memory hub 605, processor(s) 602, and I/O hub 607 can be integrated into a system on chip (SoC) integrated circuit. Alternatively, the components of the computing system 600 can be integrated into a single package to form a system in package (SIP) configuration. In some examples at least a portion of the components of the computing system 600 can be integrated into a multi-chip module (MCM), which can be interconnected with other multi-chip modules into a modular computing system.

It will be appreciated that the computing system 600 shown herein is illustrative and that variations and modifications are possible. The connection topology, including the number and arrangement of bridges, the number of processor(s) 602, and the number of parallel processor(s) 612, may be modified as desired. For instance, system memory 604 can be connected to the processor(s) 602 directly rather than through a bridge, while other devices communicate with system memory 604 via the memory hub 605 and the processor(s) 602. In other alternative topologies, the parallel processor(s) 612 are connected to the I/O hub 607 or directly to one of the one or more processor(s) 602, rather than to the memory hub 605. In other examples, the I/O hub 607 and memory hub 605 may be integrated into a single chip. It is also possible that two or more sets of processor(s) 602 are attached via multiple sockets, which can couple with two or more instances of the parallel processor(s) 612.

Some of the particular components shown herein are optional and may not be included in all implementations of the computing system 600. For example, any number of add-in cards or peripherals may be supported, or some components may be eliminated. Furthermore, some architectures may use different terminology for components similar to those illustrated in FIG. 6. For example, the memory hub 605 may be referred to as a Northbridge in some architectures, while the I/O hub 607 may be referred to as a Southbridge.

Illustrative examples of the technologies disclosed herein are provided below. An embodiment of the technologies may include any one or more, and any compatible combination of, the examples described below.

Example 1 is an apparatus that includes first and second resistor nodes and interconnect line segments. The interconnect line segments are coupled in series between the first and second resistor nodes, and the interconnect line segments include trench contacts disposed on at least one dummy transistor.

Example 2 includes the subject matter of example 1, and wherein the interconnect line segments include M0 metalization layer line segments.

Example 3 includes the subject matter of any of examples 1-2, and wherein the M0 metalization layer line segments are coupled together with the trench contacts through trench layer vias in a serpentine configuration.

Example 4 includes the subject matter of any of examples 1-3, and wherein the interconnect line segments include M1 metalization layer segments.

Example 5 includes the subject matter of any of examples 1-4, and wherein the M1 metalization layer segments are arranged in a serpentine configuration within the M1 metalization layer.

Example 6 includes the subject matter of any of examples 1-5, and wherein the interconnect line segments are configured to provide a resistance in the range of 1 K Ohm to 10 K Ohm between the first and second resistor nodes.

Example 7 includes the subject matter of any of examples 1-6, and wherein the first and second resistor nodes are implemented with interconnect line segments in one or two metalization layers of an integrated circuit device.

Example 8 includes the subject matter of any of examples 1-7, and wherein the first and second resistor nodes are implemented with interconnect line segments in an M2 metalization layer of the integrated circuit device.

Example 9 includes the subject matter of any of examples 1-8, and wherein at least one dummy transistor is electrically decoupled from an integrated circuit substrate from which the at least one dummy transistors are formed.

Example 10 is a sense circuit apparatus that includes a multiplexer circuit and an analog-to-digital circuit. The multiplexer circuit includes two or more bootstrap switch circuits. The analog-to-digital converter is coupled to an output of the multiplexer circuit. The multiplexer circuit includes at least one bootstrap switch circuit with a resistor. The resistor consists of first and second resistor nodes and interconnect line segments coupled in series between the first and second resistor nodes. The interconnect line segments include trench contacts disposed on at least one dummy transistor.

Example 11 includes the subject matter of example 10, and wherein the interconnect line segments include M0 metalization layer line segments.

Example 12 includes the subject matter of any of examples 10-11, and wherein the M0 metalization layer line segments are coupled together with the trench contacts through trench layer vias in a serpentine configuration.

Example 13 includes the subject matter of any of examples 10-12, and wherein the interconnect line segments include M1 metalization layer segments.

Example 14 includes the subject matter of any of examples 10-13, and wherein the M1 metalization layer segments are arranged in a serpentine configuration within the M1 metalization layer.

Example 15 includes the subject matter of any of examples 10-14, and wherein the interconnect line segments are configured to provide a resistance in the range of 1 K Ohm to 10 K Ohm between the first and second resistor nodes.

Example 16 includes the subject matter of any of examples 10-15, and wherein the first and second resistor nodes are implemented with interconnect line segments in one or two metalization layers of an integrated circuit device.

Example 17 includes the subject matter of any of examples 10-16, and wherein the first and second resistor nodes are implemented with interconnect line segments in an M2 metalization layer of the integrated circuit device.

Example 18 includes the subject matter of any of examples 10-17, wherein at least one dummy transistor is electrically decoupled from an integrated circuit substrate used to form the at least one dummy transistor.

Example 19 is an integrated circuit device that includes a plurality of the sense circuit apparatuses as recited in any of examples 10-18.

Example 20 is a process of making a resistor in an integrated circuit (IC) device. The process includes: forming first and second resistor nodes in at least one metalization layer of the IC device, and coupling interconnect line segments in series between the first and second resistor nodes. The interconnect line segments include trench contacts disposed on at least one dummy transistor.

Example 21 includes the subject matter of example 20, and wherein the interconnect line segments include M0 metalization layer line segments.

Example 22 includes the subject matter of any of examples 20-21, and wherein the M0 metalization layer line segments are coupled together with the trench contacts through trench layer vias in a serpentine configuration.

Example 23 includes the subject matter of any of examples 20-22, and wherein the interconnect line segments include M1 metalization layer segments.

Example 24 includes the subject matter of any of examples 20-23, and wherein the M1 metalization layer segments are arranged in a serpentine configuration within the M1 metalization layer.

Example 25 includes the subject matter of any of examples 20-24, and wherein the interconnect line segments are configured to provide a resistance in the range of 1 K Ohm to 10 K Ohm between the first and second resistor nodes.

Example 26 includes the subject matter of any of examples 20-25, and wherein the first and second resistor nodes are implemented with interconnect line segments in one or two metalization layers of the integrated circuit device.

Example 27 includes the subject matter of any of examples 20-26, wherein the first and second resistor nodes are implemented with interconnect line segments in an M2 metalization layer of the integrated circuit device.

Example 28 includes the subject matter of any of examples 20-27, wherein at least one dummy transistor is electrically decoupled from a substrate of the integrated circuit.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included.

Throughout the specification, and in the claims, the term “connected” means a direct connection, such as an electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “circuit” or “module” may refer to one or more passive and/or active components that are arranged to cooperate with one another to provide a desired function. It should be appreciated that different circuits or modules may consist of separate components, they may include both distinct and shared components, or they may consist of the same components. For example, A controller circuit may be a first circuit for performing a first function, and at the same time, it may be a second controller circuit for performing a second function, related or not related to the first function.

The meaning of “in” includes “in” and “on” unless expressly distinguished for a specific description.

The terms “substantially,” “close,” “approximately,” “near,” and “about,” unless otherwise indicated, generally refer to being within +/−10% of a target value.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

It is pointed out that those elements of the figures having the same reference numbers (or names) as the elements of any other figure can operate or function in any manner similar to that described but are not limited to such.

For purposes of the embodiments, unless expressly described differently, the transistors in various circuits and logic blocks described herein may be implemented with any suitable transistor type such as field effect transistors (FETs) or bipolar type transistors. FET transistor types may include but are not limited to metal oxide semiconductor (MOS) type FETs such as tri-gate, FinFET, and gate all around (GAA) FET transistors, as well as tunneling FET (TFET) transistors, ferroelectric FET (FeFET) transistors.

In the drawings of the embodiments, signals are represented with lines. Some lines may appear different from others, for example, thicker or hatched, to distinguish from other depicted signals for ease of understanding. Along these lines, some signal lines may have arrows at one or more ends, to indicate a primary direction of information flow. However, such indications are not intended to be limiting. Rather, lines are used in connection with one or more exemplary embodiments in a given figure to facilitate easier understanding of concepts embodied in block, circuit, and/or flow diagrams. Any represented signal, as dictated by design needs or preferences, may actually comprise one or more signals that may travel in either direction and may be implemented with any suitable type of signal scheme, e.g., analog, digital, wired, wireless, upon the platform within which the present disclosure is to be implemented.

As defined herein, the term “computer readable storage medium” means a storage medium that contains or stores program code for use by or in connection with an instruction execution system, apparatus, or device. As defined herein, a “computer readable storage medium” is not a transitory, propagating signal per se. A computer readable storage medium may be, but is not limited to, an electronic storage device, a magnetic storage device, an optical storage device, an electromagnetic storage device, a semiconductor storage device, or any suitable combination of the foregoing. Memory elements, as described herein, are examples of a computer readable storage medium.

As defined herein, the term “processor” means at least one hardware circuit configured to carry out instructions contained in program code. The hardware circuit may be implemented with one or more integrated circuits. Examples of a processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, a graphics processing unit (GPU), a controller, and so forth. It should be appreciated that a logical processor, on the other hand, is a processing abstraction associated with a core, for example, when one or more SMT cores are being used, such that multiple logical processors may be associated with a given core, for example, in the context of core thread assignment.

It should be appreciated that a processor or processor system may be implemented in various different manners. For example, they may be implemented on a single die, multiple dies (dielets, chiplets), one or more dies in a common package, or one or more dies in multiple packages. Along these lines, some of these blocks may be located separately on different dies or together on two or more different dies.

While the flow diagrams in the figures show a particular order of operations performed by certain embodiments of the invention, it should be understood that such order is exemplary (e.g., alternative embodiments may perform the operations in a different order, combine certain operations, overlap certain operations, etc.).

While the invention has been described in terms of several embodiments, those skilled in the art will recognize that the invention is not limited to the embodiments described, can be practiced with modification and alteration within the spirit and scope of the appended claims. The description is thus to be regarded as illustrative instead of limiting.

What is claimed is:

1. An apparatus, comprising:
first and second resistor nodes; and
interconnect line segments coupled in series between the first and second resistor nodes, wherein the interconnect line segments include trench contacts disposed on at least one dummy transistor.

2. The apparatus of claim 1, wherein the interconnect line segments include M0 metalization layer line segments.

3. The apparatus of claim 2, wherein the M0 metalization layer line segments are coupled together with the trench contacts through trench layer vias in a serpentine configuration.

4. The apparatus of claim 1, wherein the interconnect line segments include M1 metalization layer segments.

5. The apparatus of claim 4, wherein the M1 metalization layer segments are arranged in a serpentine configuration within the M1 metalization layer.

6. The apparatus of claim 1, wherein the interconnect line segments are configured to provide a resistance in the range of 1 K Ohm to 10 K Ohm between the first and second resistor nodes.

7. The apparatus of claim 1, wherein the first and second resistor nodes are implemented with interconnect line segments in one or two metalization layers of an integrated circuit device.

8. The apparatus of claim 7, wherein the first and second resistor nodes are implemented with interconnect line segments in an M2 metalization layer of the integrated circuit device.

9. The apparatus of claim 1, wherein at least one dummy transistor is electrically decoupled from an integrated circuit substrate from which at least one dummy transistors are formed.

10. A sense circuit apparatus, comprising:
a multiplexer circuit including two or more bootstrap switch circuits; and
and an analog-to-digital converter coupled to an output of the multiplexer circuit, wherein the multiplexer circuit includes at least one bootstrap switch circuit with a resistor that provides for:
first and second resistor nodes; and
interconnect line segments coupled in series between the first and second resistor nodes, wherein the interconnect line segments include trench contacts disposed on at least one dummy transistor.

11. The apparatus of claim 10, wherein the interconnect line segments include M0 metalization layer line segments.

12. The apparatus of claim 11, wherein the M0 metalization layer line segments are coupled together with the trench contacts through trench layer vias in a serpentine configuration.

13. The apparatus of claim 10, wherein the interconnect line segments include M1 metalization layer segments.

14. The apparatus of claim 13, wherein the M1 metalization layer segments are arranged in a serpentine configuration within the M1 metalization layer.

15. The apparatus of claim 10, wherein the interconnect line segments are configured to provide a resistance in the range of 1 K Ohm to 10 K Ohm between the first and second resistor nodes.

16. The apparatus of claim 10, wherein at least one dummy transistor is electrically decoupled from an integrated circuit substrate used to form at least one dummy transistor.

17. An integrated circuit device that includes a plurality of the sense circuit apparatuses as recited in claim 10.

18. A process of making a resistor in an integrated circuit (IC) device, comprising:
forming first and second resistor nodes in at least one metalization layer of the IC device; and
coupling interconnect line segments in series between the first and second resistor nodes, wherein the interconnect line segments include trench contacts disposed on at least one dummy transistor.

19. The process of claim 18, including coupling M0 metalization layer line segments together with the trench contacts through trench layer vias in a serpentine configuration.

20. The process of claim 19, wherein at least one dummy transistor is electrically decoupled from a substrate of the integrated circuit device.
